(19) United States
(12) Patent Application Publication
(10) Pub. No.: US 2002/0027011 A1
(43) Pub. Date: Mar. 7, 2002

(54) Multi-chip module made of a low temperature co-fired ceramic and mounting method thereof

(76) Inventor: Chul Soon Park, Daejeon (KR)

Correspondence Address: BACON & THOMAS, PLLC, 625 SLATERS LANE, FOURTH FLOOR, ALEXANDRIA, VA, 22314

(21) Appl. No.: 09/892,760

(22) Filed: Jun. 28, 2001

(30) Foreign Application Priority Data
Aug. 21, 2000 (KR) 2000-48256
Aug. 21, 2000 (KR) 2000-48258

(51) Int. Cl. H01L 23/02

(52) U.S. Cl. 174/52.4

(57) ABSTRACT

A module for mounting chips therein includes base layers for forming floors on which the chips are mounted and cavity layers having cavities through which the chips are mounted on the floors. The floors has a top surface provided with contact regions for electrical connection with the chips and the cavity layers has a top surface provided with bonding pads for electrical connection with a printed circuit board. The cavity layers are disposed on the top surface of the base layers to expose the contact regions through the cavities.

### FIELD OF THE INVENTION

The present invention relates to a multi-chip module made of a low temperature co-fired ceramic and a method for mounting the module on a printed circuit board (“PCB”); and, more particularly, to a multi-chip module having a simple configuration and an improved heat release efficiency and a method for easily integrating the module to the PCB.

### BACKGROUND OF THE INVENTION

Various types of modules, packages or other electronic circuit structures are utilized in the electronic industry. Such modules or packages are employed in a variety of electronic devices including, for example, personal computers, communications devices, and military devices such as a radar and an armament control system. Electronic circuit structures such as multi-chip module (“MCM”) circuit structures are often formed of a dielectric material such as a low temperature co-fired ceramic (“LTCC”) dielectric tape. Some of these structures include cavities used for mounting semiconductor devices. The rest of the outer surfaces of the structures may be used to mount capacitors, inductors, varistors and other electronic components or devices.

One of the prior art electronic circuit structures is described in U.S. Pat. No. 5,455,385 entitled “MULTILAYER LTCC TUB ARCHITECTURE FOR HERMETICALLY SEALING SEMICONDUCTOR DIE, EXTERNAL ELECTRICAL ACCESS FOR WHICH IS PROVIDED BY WAY OF SIDEWALL RECESSES”. The prior art packaging assembly is formed of a hermetically sealable “tub”-like structure. The tub-like structure includes a laminated stack of thin layers of low temperature co-fired ceramic material. The laminated stack of LTCC layers has an internally distributed network of interconnect links through which a semiconductor die mounted on a floor of the tub by using an attachment material is electrically connected to a plurality of conductive recesses located on top and bottom sidewall edge portions of the tub, thereby allowing multiple tubs to be joined together as a hermetically sealed assembly and electrically interconnected at the conductive recesses of adjacent tubs.

In such a packaging assembly, the task of attaching process of the semiconductor die becomes rather tricky and cumbersome. Further, since heat generated from the die is released through the underlying tub floor, the heat release efficiency decreases.

Another prior art electronic circuit structure is described in U.S. Pat. No. 5,600,541 entitled “VERTICAL IC CHIP STACK WITH DISCRETE CHIP CARRIERS FORMED FROM DIELECTRIC TAPE”. The vertical IC chip stack includes a plurality of discrete chip carriers formed of dielectric tape layers such as fused LTCC tape. The chips are lodged in cavities within the tape layers and connected to electrical routings that extend along one or more tape layers toward the periphery of the carrier. Interconnects for the carriers are provided between the routings for adjacent carriers. The carriers are mechanically secured to each other within the stack by, e.g., connectors.

Such an assembly employs dielectric spacers extending from each chip to the underside of the carrier for a next upper chip so as to assist in extracting heat therefrom and an air-tight lid for hermetic sealing attached over the uppermost carrier, thereby making the process complicate.

### SUMMARY OF THE INVENTION

It is, therefore, an object of the present invention to provide a multi-chip module having a simple configuration and an improved heat release efficiency and a method for easily integrating the module into a printed circuit board.

In accordance with one aspect of the present invention, there is provided a module for mounting at least one chip therein, comprising:

a stacked laminate including at least one base layer for forming at least one floor on which the chip is mounted, top of the floor being provided with at least one contact region for electrical connection with the chip; and

at least one cavity layer having at least one cavity through which the chip is mounted on the floor, top of the cavity layer being provided with at least one bonding pad for electrical connection with a printed circuit board,

wherein the cavity layer is disposed on top of the base layer to expose the contact region through the cavity.

In accordance with another aspect of the present invention, there is provided a method for mounting a module on a printed circuit board, comprising the steps of:

forming at least one bonding pad for electrical connection with the printed circuit board on top of the module;

forming at least one mating bonding pad on top of the printed circuit board; and

electrically connecting the bonding pad to the mating bonding pad.

### BRIEF DESCRIPTION OF THE DRAWINGS

The above and other objects and features of the present invention will become apparent from the following description of the preferred embodiments given in conjunction with the accompanying drawings, in which:

FIG. 1 shows a perspective view of a multi-chip module in accordance with the present invention;

FIGS. 2A to 2C illustrate top views of respective base layers constituting the multi-chip module shown in FIG. 1;

FIGS. 3A to 3C present top views of respective cavity layers constituting the multi-chip module shown in FIG. 1;

FIG. 4 discloses a partial schematic perspective view of the multi-chip module in accordance with the present invention mounted on a printed circuit board;

FIG. 5 describes a perspective view of the multi-chip module in accordance with the present invention where chips are mounted;

FIG. 6 depicts a view setting forth a process of mounting the multi-chip module in accordance with the present invention on a printed circuit board; and

FIG. 7 represents a view setting forth a process of connecting the multi-chip module in accordance with the present invention to another multi-chip module.

### DETAILED DESCRIPTION OF THE PREFERRED EMBODIMENTS

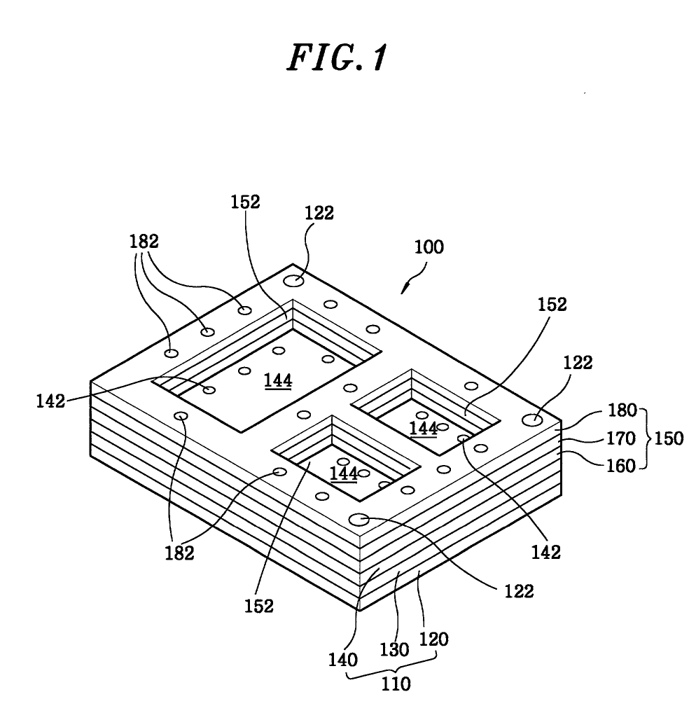

Referring to FIG. 1, there is illustrated a perspective view of a multi-chip module 100 in accordance with the present invention.

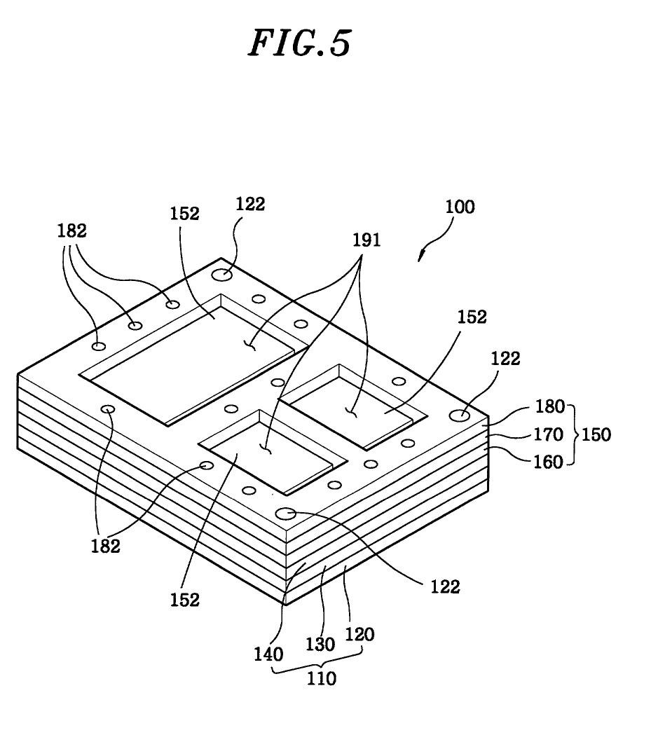

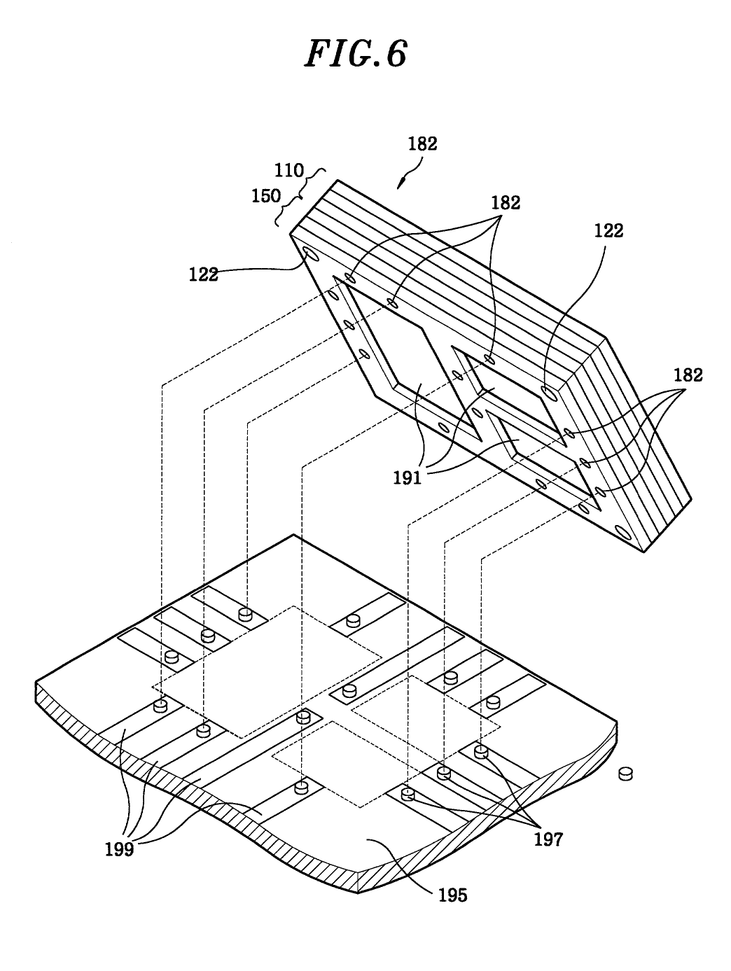

The inventive multi-chip module 100 comprises a stacked laminate of multiple layers of thin dielectric layers made of, e.g., low temperature co-fired ceramic material. The stacked laminate has a base structure 110 for forming one or more floors, e.g., three floors 144 for mounting chips 191 thereon (see FIG. 5) and a cavity structure 150 having one or more cavities, e.g., three cavities 152 through which the chips 191 are mounted on the floors 144.

The base structure 110 includes one or more stacked layers, e.g., a lower, a middle, an upper layers 120, 130, 140, and the cavity structure 150 is disposed on the base structure 110 and includes one or more cavity layers, e.g., a lower, a middle, an upper layer 160, 170, 180.

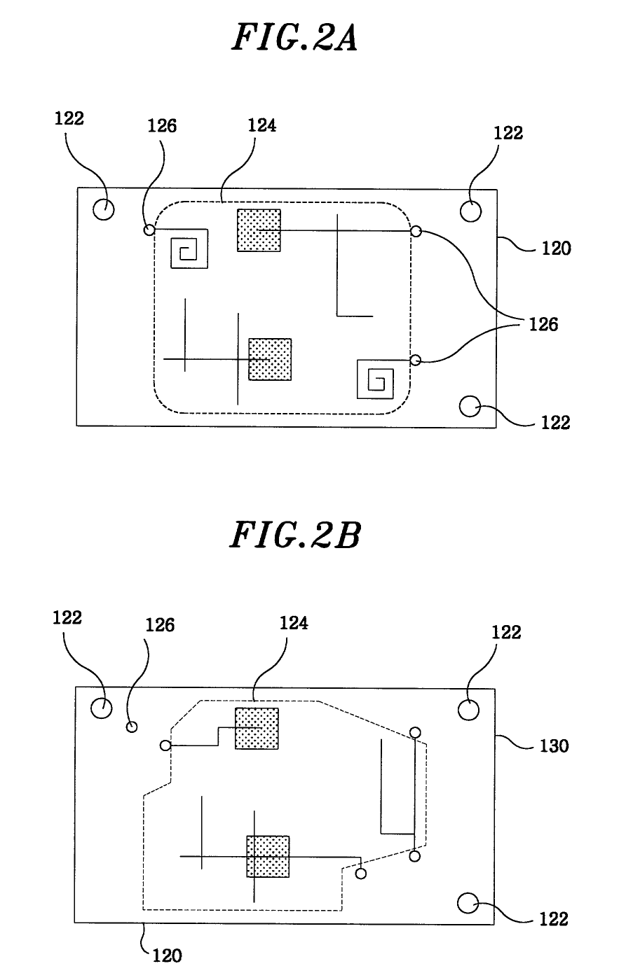

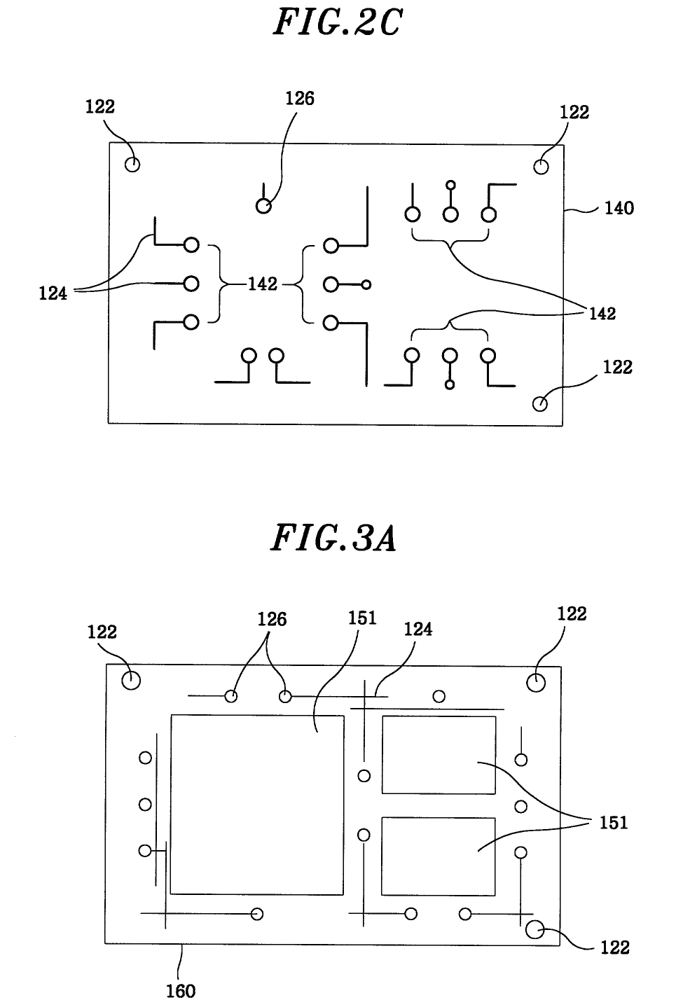

As shown in FIGS. 2A, 2B and 2C illustrating top views of respective base layers 120, 130, 140 of the base structure 110 in accordance with the present invention, the layers 120, 130, 140 of the base structure 110 have positioning holes 122 for aligning with adjacent layers, conductor patterns 124 for desired electrical circuits, vias 126, filled with a conductive material, e.g., Pt or Al, for electrically interconnecting the conductor patterns 124 of the individual layers and/or passive electrical components (not shown) such as resistors or inductors.

As clearly shown in FIG. 2C, the upper layer 140 of the base structure 110 further has contact regions 142 on its top for electrical connection with terminal pads (not shown) of the chips 191 which are to be mounted on the floors 144.

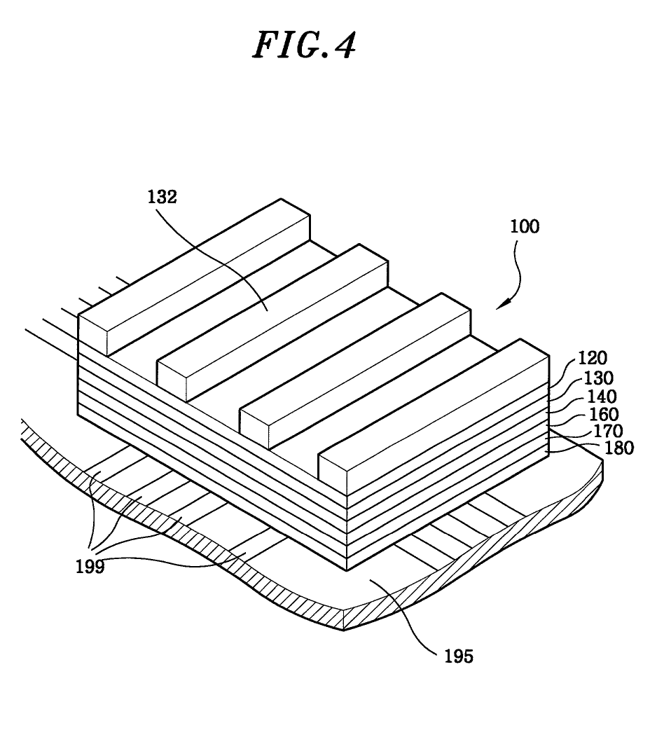

The lower layer 120 of the base structure 110 further has on its bottom surface heat radiation fins 132 for releasing heat generated from the multi-chip module 100 (see FIG. 4).

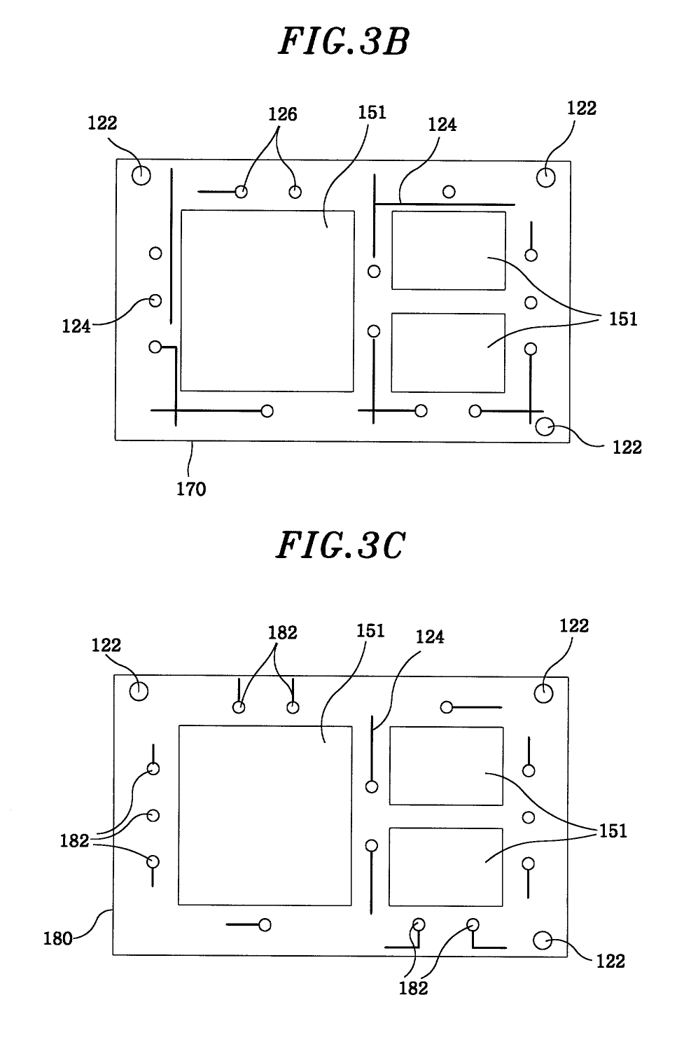

With reference to FIGS. 3A, 3B and 3C showing top views of respective cavity layers 160, 170, 180 of the cavity structure 150 in accordance with the present invention, similar to the base structure 110, each of the layers 160 and 170 of the cavity structure 150 has the positioning holes 122, the conductor patterns 124 and the vias 126 and the layer 180 thereof has the positioning holes 122 and the conductor patterns 124. Further, the layers 160, 170, 180 of the cavity structure 150 are respectively provided with one or more cut-outs or openings 151 to form the cavities 152 for accommodating the chips 191. As apparently shown in FIG. 3C, the upper layer 180 of the cavity structure 150 further has on its top one or more bonding pads 182 for electrical connection with a printed circuit board 195 having one or more mating bonding pads 197 located on conductor patterns 199 thereof (see FIG. 6).

The manufacturing process of the inventive multi-chip module 100 will now be described in detail.

First, the layers 120, 130, 140 of the base structure 110 are stacked on top of another in such a manner that their positioning holes 122 are aligned with each other. Similarly, the layers 160, 170, 180 of the cavity structure 150 are also stacked. Next, the cavity structure 150 is disposed on the upper layer 140 of the base structure 110 in such a way that the contact regions 142 of the base structure 110 are exposed through the cavities 152 of the cavity structure 150. Finally, the base and the cavity structure 110, 150 are sintered to form the multi-chip module 100 shown in FIG. 1.

Next, as shown in FIG. 5 showing a perspective view of the multi-chip module 100 where chips 191 are mounted, the chips 191 are respectively mounted on the floors 144 of the base structure 110 through their corresponding cavities 152 so that the chips 191 are electrically connected to the electrical circuits of the multi-chip modules 100 through the terminal pads and the contact regions 142.

Subsequently, as shown in FIG. 6 showing a view setting forth a process of mounting the multi-chip module 100 on the printed circuit board 195, after upsetting the module 100, the bonding pads 182 of the module 100 and the mating bonding pads 197 of the PCB 195 are electrically connected to each other, mounting the multi-chip module 100 on the PCB 195.

Finally, the space between the chips 191 and the PCB 195 is typically filled with, e.g., a nonconductive polymeric material, as known in the art, to mutually isolate the conductive connections and assist in mechanically joining the module 100 to the PCB 195.

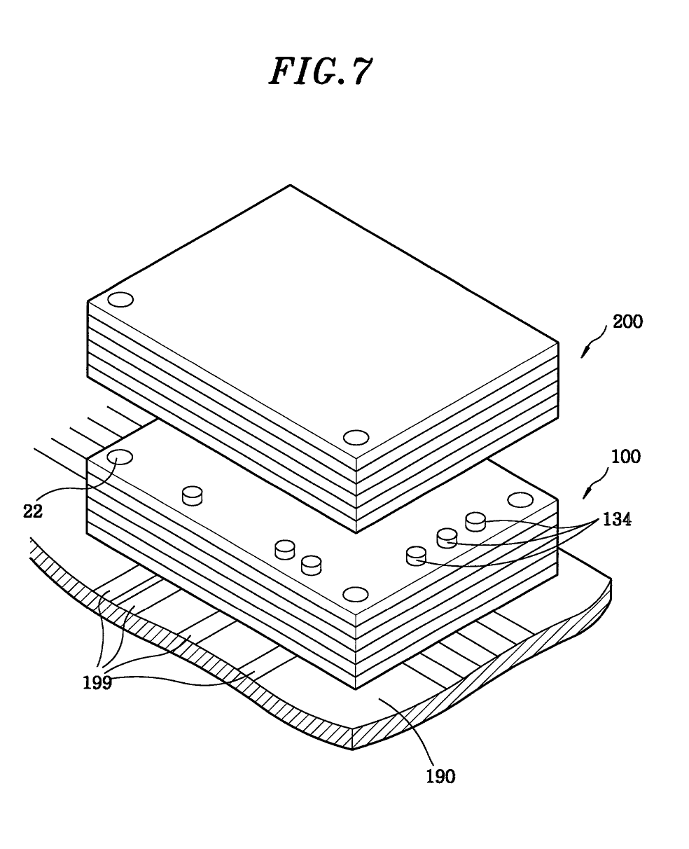

As shown in FIG. 7 showing a view setting forth a process of connecting the multi-chip module 100 to another multi-chip module 200, the lower layer 120 of the base structure 110 of the module 100 may have on its bottom one or more contact points 134 for electrical connection with, e.g., another multi-chip module 200 having mating contact points (not shown). This arrangement allows a plurality of modules to be connected to each other

In such a module, since the heat radiation fins are installed at the bottom of the module, the heat release efficiency is improved. Further, it is possible to easily integrate the module to the print circuit board and/or another module.

While the invention has been shown and described with respect to the preferred embodiments, it will be understood by those skilled in the art that various changes and modifications may be made without departing from the spirit and scope of the invention as defined in the following claims.

What is claimed is:

1. A module for mounting at least one chip therein, comprising:
a stacked laminate including
at least one base layer for forming at least one floor on which said at least one chip is mounted, top of said at least one floor being provided with at least one contact region for electrical connection with said at least one chip; and
at least one cavity layer having at least one cavity through which said at least one chip is mounted on said at least one floor, top of the cavity layer being provided with at least one bonding pad for electrical connection with a printed circuit board,
wherein said at least one cavity layer is disposed on the top of said at least one base layer to expose said at least one contact region through said at least one cavity.

2. The module of claim 1, wherein the printed circuit board has at least one mating bonding pad corresponding said at least one bonding pad of the cavity layer, the cavity layers being electrically connected to the printed circuit board by electrically connecting said at least one bonding pad and said at least one mating bonding pad to each other.

3. The module of claim 1, wherein said at least one base layer has heat radiation fins at its bottom.

4. The module of claim 1, wherein the base and the cavity layers are dielectric layers made of low temperature co-fired ceramic material.

5. The module of claim 1, wherein said at least one base layer has at its bottom at least one contact point for electrical connection with another module.

6. A method for mounting the module of claim 2 on the printed circuit board, comprising the steps of:
forming at least one bonding pad for electrical connection with the printed circuit board on top of the module;
forming at least one mating bonding pad on top of the printed circuit board; and
electrically connecting said at least one bonding pad to said at least one mating bonding pad.
